(19) United States
(12) Patent Application Publication
(10) Pub. No.: US 2018/0128856 A1
(43) Pub. Date: May 10, 2018

(54) SYSTEM AND METHOD FOR PROVIDING INFORMATION ON CURRENT STATE OF BUSINESS OF LOCAL GOODS OR SERVICES PROVIDER

(71) Applicant: Korea Electric Power Corporation, Naju-si, Jeollanam-do (KR)

(72) Inventors: Young-Sung LEE, Daejeon (KR); Chung-Hyo KIM, Daejeon (KR); Jung-Seok BAE, Daejeon (KR)

(21) Appl. No.: 15/569,725

(22) PCT Filed: Aug. 2, 2016
(86) PCT No.: PCT/KR2016/008520

§ 371 Date: Oct. 26, 2017

(30) Foreign Application Priority Data
Aug. 20, 2015 (KR) 10-2015-0117249

(51) Int. Cl. G01R 11/30; G06Q 50/06; G06Q 10/06; G06Q 10/10

(52) U.S. Cl. CPC G01R 11/30; G06Q 10/109; G06Q 10/063; G06Q 50/06

(57) ABSTRACT

The system for providing information on the current state of business of the local goods or services provider comprises: a power consumption information collection unit for collecting power consumption information of the local goods or services provider; a power consumption information analysis unit for analyzing the power consumption information, and extracting a feature of an amount of power consumption of the local goods or services provider; and a business open-or-closed determination unit for determining whether the local goods or services provider is open for business at a predetermined point in time, on the basis of the feature of the amount of power consumption of the local goods or services provider, and providing information on whether the local goods or services provider is open for business.

### BACKGROUND OF THE INVENTION

### Field of the Invention

The present disclosure relates to a system and method for providing information on the current state of business of a local goods or services provider.

### Related Art

Portal sites (e.g., Naver, Daum, and the like) are able to provide information on a local goods or services provider (i.e., a facility adjacent to a residential area to allowing residents to obtain goods or services) through current location search.

However, existing portal sites do not provide information on whether the local goods or services providers are actually open for business at the time of making a search, so a user is required to make a call, or the like, to check whether the local goods or services provider is open for business, before visiting. In particular, in the case of a hospital, a drug store, or the like, often providing goods and services only for a limited period of time on holidays or on weekends, it is essential for a user to determine whether such a business is currently open.

In addition, even after determining whether the local goods or services provider is currently open for business, if the user does not have information on the closing time of the business, the business may close during the time required for physical movement (i.e., before the user reaches the local goods or services provider), and thus, this situation is required to be considered.

### SUMMARY OF THE INVENTION

An aspect of the present disclosure may provide a method for providing information on whether a local goods or services provider is open for business at the time at which the local goods or services provider is searched or information on a due opening/closing time of the local goods or services provider together, when information on the local goods or services provider is provided on the basis of the current location.

According to an aspect of the present disclosure, a system for providing information on the current state of business of a local goods or services provider is provided. The system for providing information on the current state of business of a local goods or services provider includes: a power consumption information collection unit collecting power consumption information of the local goods or services provider; a power consumption information analysis unit analyzing the power consumption information collected by the power consumption information collection unit, and extracting a feature of the amount of power consumption of the local goods or services provider; and a business open-or-closed determination unit determining whether the local goods or services provider is open for business at a predetermined point in time, on the basis of the feature of the amount of power consumption of the local goods or services provider analyzed by the power consumption information analysis unit, and providing information on whether the local goods or services provider is open for business.

According to another aspect of the present disclosure, a method for providing information on the current state of business of a local goods or services provider is provided. The method for providing information on the current state of business of a local goods or services provider includes: measuring an amount of power consumption of a local goods or services provider; analyzing measured power consumption information; determining whether the local goods or services provider is open for business on the basis of an analysis result; and mapping information on whether the local goods or services provider is open for business with information of the local goods or services provider and providing mapped information.

The foregoing technical solutions do not fully enumerate all of the features of the present disclosure. The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a block diagram illustrating a system for providing information on the current state of business of a local goods or services provider according to an exemplary embodiment of the present disclosure.

FIG. 2 is a view illustrating an example of an open-or-closed determination algorithm of a business open-or-closed determination unit illustrated in FIG. 1.

FIG. 3A, FIG. 3B, FIG. 3C and FIG. 3D are views illustrating various examples in which information on the current state of business of a local goods or services provider is provided by an information providing unit illustrated in FIG. 1.

FIG. 4 is a flow chart illustrating a method for providing information on the current state of business of a local goods or services provider according to another exemplary embodiment of the present disclosure.

### DESCRIPTION OF EXEMPLARY EMBODIMENTS

Hereinafter, exemplary embodiments will be described in detail with reference to the accompanying drawings such that they can be easily practiced by those skilled in the art to which the present disclosure pertains. In describing the present disclosure, if a detailed explanation for a related known function or construction is considered to unnecessarily divert the gist of the present disclosure, such explanation will be omitted but would be understood by those skilled in the art. Also, similar reference numerals are used for the similar parts throughout the specification.

It will be understood that when an element is referred to as being “connected to” another element, it can be directly connected to the other element or intervening elements may also be present. In contrast, when an element is referred to as being “directly connected to” another element, no intervening elements are present. In addition, unless explicitly described to the contrary, the word “comprise” and variations such as “comprises” or “comprising,” will be understood to imply the inclusion of stated elements but not the exclusion of any other elements.

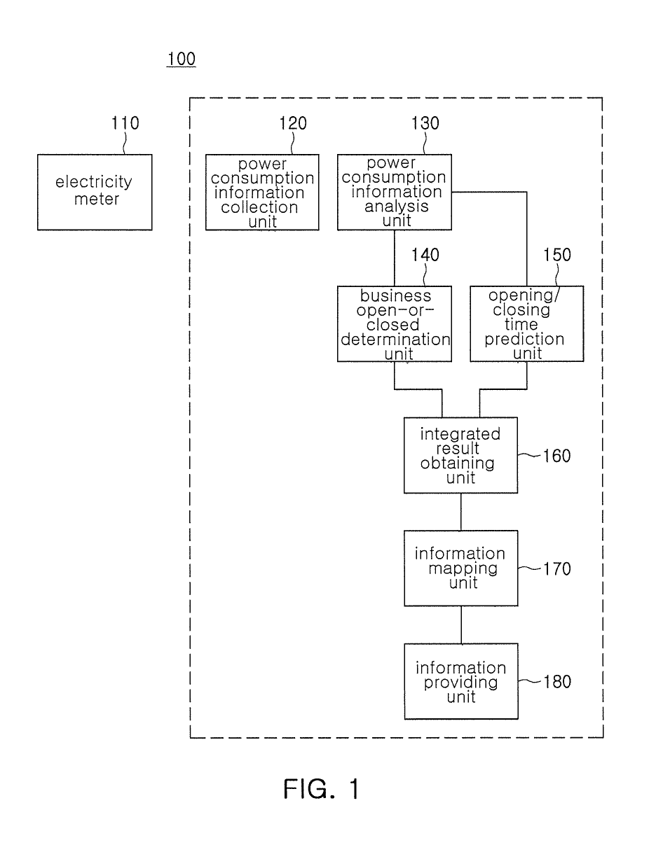

FIG. 1 is a block diagram illustrating a system for providing information on the current state of business of a local goods or services provider according to an exemplary embodiment of the present disclosure.

Referring to FIG. 1, a system 100 for providing information on the current state of business of a local goods or services provider according to an exemplary embodiment of the present disclosure may include an electricity meter 110, a power consumption information collection unit 120, a power consumption information analysis unit 130, a business open-or-closed determination unit 140, an opening/closing time prediction unit 150, an integrated result obtaining unit 160, an information mapping unit 170, and an information providing unit 180.

The electricity meter 110 may be installed in a local goods or services provider to measure an amount of power consumption of the corresponding local goods or services provider.

According to an exemplary embodiment, the electricity meter 110 may be installed per local goods or services provider to measure a total amount of power consumption of the corresponding local goods or services provider. According to another exemplary embodiment, the electricity meter 110 may be installed in each major device provided in a local goods or services provider to measure an amount of power consumption of the corresponding device.

The electricity meter 110 may periodically measure an amount of power consumption and deliver measured power consumption information to the power consumption information collection unit 120 (to be described hereinafter) together with a unique identifier (ID) of the corresponding local goods or services provider.

The power consumption information collection unit 120 serves to collect power consumption information from the electricity meter 110 installed in the local goods or services provider.

Here, the power consumption information collection unit 120 may have a communication function to collect power consumption information, and may perform communications based on various wired/wireless communication schemes known to a person skilled in the art.

The power consumption information analysis unit 130 serves to analyze power consumption information of the local goods or services provider collected by the power consumption information collection unit 120 to extract a feature of the amount of power consumption of the corresponding local goods or services provider.

Here, the power consumption information analysis unit 130 may extract the feature of the amount of power consumption according to classification of business, area, and the like, of the local goods or services provider through statistical and logical computation of the power consumption information.

The business open-or-closed determination unit 140 serves to determine whether the local goods or services provider is open for business at a corresponding time point on the basis of the feature of the amount of power consumption of the corresponding local goods or services provider analyzed by the power consumption information analysis unit 130. Here, the business open-or-closed determination unit 140 may determine whether the local goods or services provider is open for business in various manners as described hereinafter.

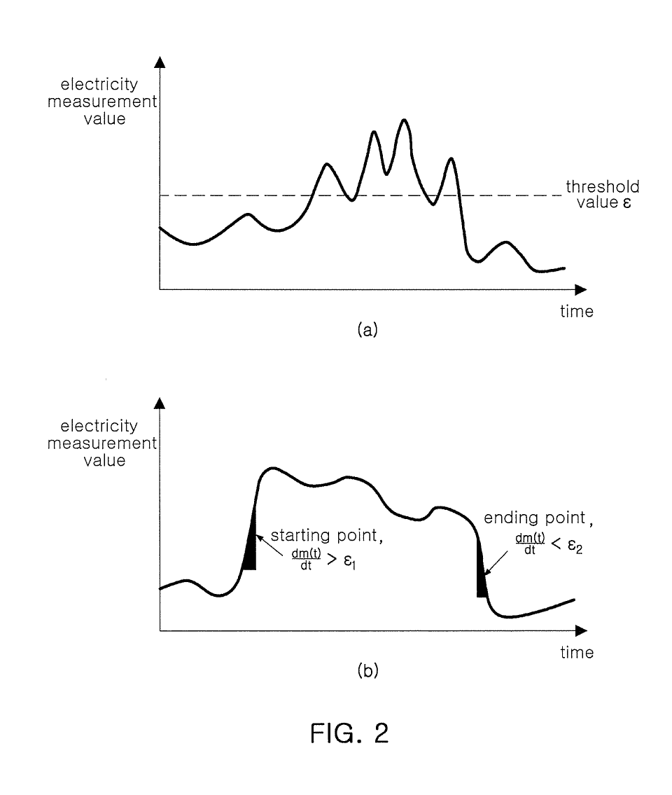

According to an exemplary embodiment, as illustrated in (a) of FIG. 2, the business open-or-closed determination unit 140 may determine whether the corresponding local goods or services provider is open for business on the basis of an absolute amount of power consumption measurement value of the local goods or services provider per unit time. Here, the power consumption information analysis unit 130 may compare the amount of power consumption measurement value per unit time with a preset absolute threshold value (s), and when the measurement value exceeds the absolute threshold value (s), the power consumption information analysis unit 130 may determine that the local goods or services provider is open for business.

According to another exemplary embodiment, as illustrated in (b) of FIG. 2, the business open-or-closed determination unit 140 may determine whether the corresponding local goods or services provider is open for business on the basis of a change in increase and decrease of an amount of power consumption measurement value per unit time. Here, the power consumption information analysis unit 130 may compare a degree of increment or decrement in an amount of power consumption measurement value per unit time analyzed by the power consumption information analysis unit 130 with a preset threshold value (ε1 when increased and ε2 when decreased, for example), and when the amount of power consumption measurement value exceeds the threshold value, the power consumption information analysis unit 130 may determine the value as a business opening time point or a business closing time point.

Also, according to another exemplary embodiment, the business open-or-closed determination unit 140 may determine whether the corresponding local goods or services provider is open for business by recognizing whether essential operating equipment, whose power is bound to be turned on or off when the corresponding local goods or services provider is open or closed, is in use according to the classification of local goods or services providers. To this end, essential operating equipment of each local goods or services provider may be selected as illustrated in Table 1.

TABLE 1

| Classification | Essential operating equipment | Ni |
|---|---|---|
| Hospital | Credit card terminal, PC for patient | 3 |
| | reception, patient diagnosis facility | |
| Drug store | Credit card terminal, PC for reception, | 3 |
| | tablet dispenser | |
| Restaurant | Credit card terminal, electric oven, | 4 |
| | ventilator fan, dishwasher | |

Such essential operating equipment may be statically or dynamically selected, and when dynamically selected, equipment which has a high possibility of indicating whether the business is open and has highest correlation according to statistical and logical technique may be selected as essential operating equipment.

Also, the business open-or-closed determination unit 140 may analyze a pattern regarding electric features, for example, an instantaneous change in amount of power consumption, noise, and the like, when the selected essential operating equipment operates, and determine whether the essential operating equipment is in use on the basis of the analyzed pattern.

In another method, a sensor generating a specific signal when the essential operating equipment operates may be installed in the essential operating equipment, and the business open-or-closed determination unit 140 may determine whether the essential operating equipment is in use on the basis of a sensor signal.

The opening/closing time prediction unit 150 serves to predict a business opening/closing time of the local goods or services provider, and here, the opening/closing time prediction unit 150 may predict a business opening/closing time in various manners as described hereinafter.

According to an exemplary embodiment, on the basis of results obtained by reflecting day information (e.g., non-business day), holiday information, event information, and the like, and by analyzing amount of power consumption measurement values accumulated for a predetermined period or longer, when the local goods or services provider is open for business at a certain time point, the opening/closing time prediction unit 150 may calculate a due closing time, and when the local goods or services provider is closed for business at a certain time point, the opening/closing time prediction unit 150 may calculate a due opening time. Also, the opening/closing time prediction unit 150 may predict an opening/closing time additionally reflecting irregular information such as weather information, epidemic information (e.g., epidemic information of a specific disease such as influenza, etc.), and the like.

In addition, the opening/closing time prediction unit 150 may predict a starting and ending time of a lunch break, as well as the opening and closing time on the basis of the aforementioned method, and provide corresponding information.

The integrated result obtaining unit 160 may receive results output from the business open-or-closed determination unit 140 and the opening/closing time prediction unit 150, that is, results of determining whether the local goods or services provider is open for business and results of predicting an opening/closing time, and integrating the results to provide an integrated result.

The aforementioned opening/closing time prediction unit 150 and the integrated result obtaining unit 160 may be selectively provided as necessary. In other words, it may be realized such that only whether the local goods or services provider is open for business may be determined by the business open-or-closed determination unit 140 and provided. Here, the information mapping unit 170 described hereinafter may map information received from the business open-or-closed determination unit 140 with information on the local goods or services provider.

The information mapping unit 170 maps the information transmitted from the integrated result obtaining unit 160 with the information on the local goods or services provider. Here, the local goods or services provider information may be provided from a company, an institution, and the like, providing existing location-based local goods or services provider information such as a portal size, or the like. Or, the result output by the integrated result obtaining unit 160 may be provided to a portal site, or the like, such that the portal site, or the like, may perform information mapping as described above.

The information providing unit 180 serves to provide information mapped by the information mapping unit 170, i.e., the information on the local goods or services provider and information on the current state of business of the corresponding local goods or services provider.

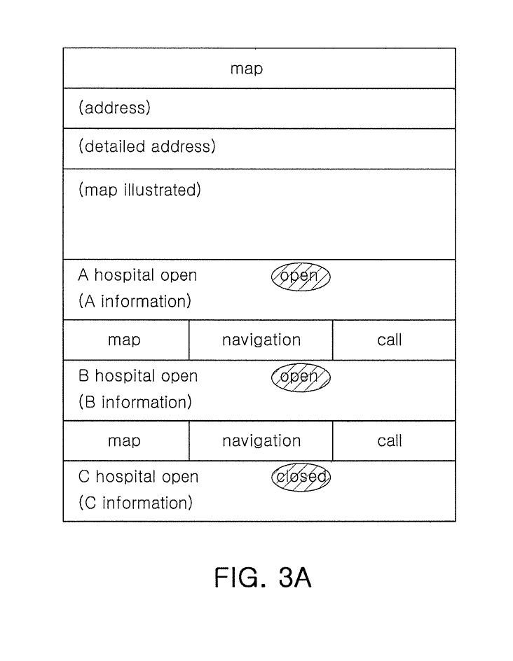

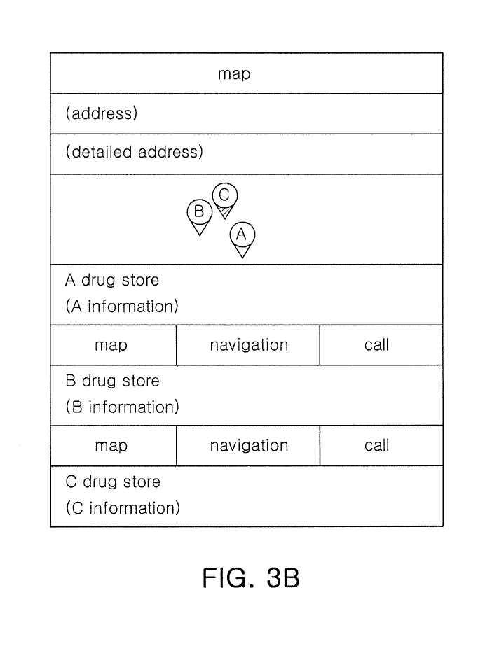

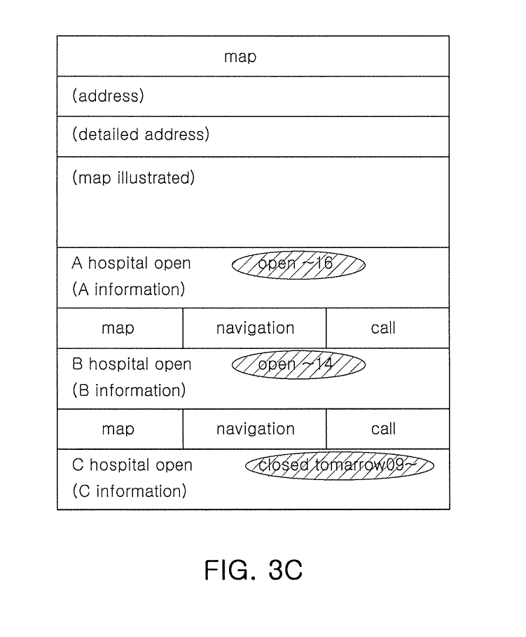

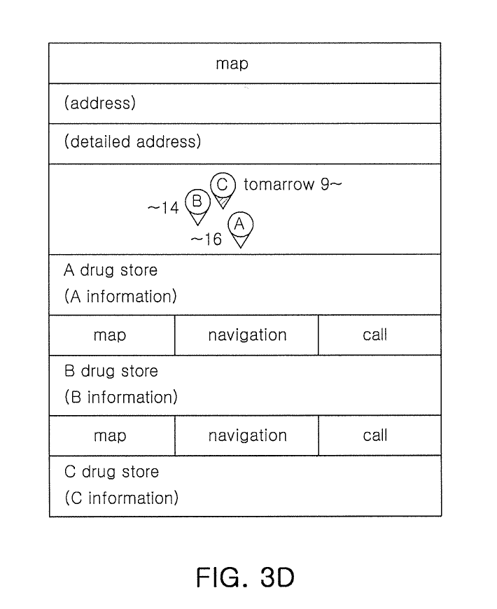

FIG. 3A, FIG. 3B, FIG. 3C and FIG. 3D are views illustrating various examples in which information on the current state of business of a local goods or services provider is provided by an information providing unit illustrated in FIG. 1.

As illustrated in FIG. 3A, the information providing unit 180 may provide information on whether a certain local goods or services provider is open for business by intuition using a combination of one or more of a phrase, a diagram, and a color indicating whether the local goods or services provider is open for business, such as “open”, “closed”, “at work”, “in service”, or the like, while providing search information on the local goods or services provider.

Also, as illustrated in FIG. 3B, the information providing unit 180 may provide information using a figure, color, and the like, intuitively indicating to a user whether a local goods or services provider searched for on a map is open for business.

Also, as illustrated in FIG. 3C, the information providing unit 180 may provide information on whether a certain local goods or services provider is open for business and an opening/closing time thereof intuitively using a combination of one or more of a phrase, a diagram, and a color indicating whether the local goods or services provider is open for business (e.g., “open”, “closed”, “at work”, “in service”, etc.) and a due opening/closing time, while providing searched information on the local goods or services provider. Here, when the corresponding local goods or services provider is open for business, the information providing unit 180 may display a due closing time, and when the corresponding local goods or services provider is closed for business, the information providing unit 180 may display a due opening time, and here, the information providing unit 180 may display the due opening time or due closing time in units of 24 hours or 12 hours (a separator for morning and afternoon is required).

Also, as illustrated in FIG. 3D, the information providing unit 180 may provide information using a phrase, a diagram, a color, and the like, intuitively indicating a due opening/closing time to a location of the searched local goods or services provider on a map, in addition to providing information on whether a local goods or services provider is open for business.

The examples of providing information illustrated in FIG. 3A, FIG. 3B, FIG. 3C and FIG. 3D may be realized independently or two or more thereof may be combined to be realized.

The system 100 for providing information on the current state of business of a local goods or services provider configured as described above may be realized as a central processing unit (CPU), a graphic processing unit (GPU), a microprocessor, an application specific integrated circuit (ASIC), a field programmable gate array (FPGA), and the like, for example.

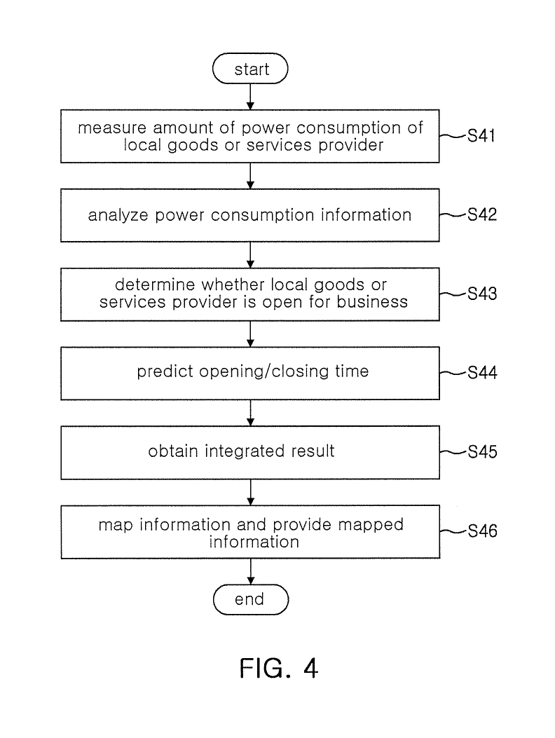

FIG. 4 is a flow chart illustrating a method for providing information on the current state of business of a local goods or services provider according to another exemplary embodiment of the present disclosure.

Referring to FIG. 4, first, an amount of power consumption of a local goods or services provider is measured in operation S41, and the measured power consumption information is analyzed in operation S42.

Thereafter, whether the corresponding local goods or services provider is open for business is determined on the basis of an analysis result in operation S43, and an opening/closing time may be additionally predicted in operation S44.

Thereafter, an integrated result is obtained by integrating the information on whether the local goods or services provider is open for business and the opening/closing time information in operation S45 and subsequently mapped with information on the local goods or services provider provided in a portal site, or the like, so as to be provided to a user in operation S46.

The method for providing information on the current state of business of a local goods or services provider illustrated in FIG. 4 may be performed by a processor, and details for performing each operation are the same as those described above with reference to FIG. 1, and thus, a redundant description thereof will be omitted.

As set forth above, according to exemplary embodiments of the present disclosure, whether a local goods or services provider is open for business when the local goods Or services provider is searched, and in addition, an opening/closing time of the local goods or services provider may be provided to the user by utilizing an electricity measurement value of the local goods or services provider. Thus, the user does not need to directly check whether the local goods or services provider is open for business through a call, or the like, after searching for the local goods or services provider, and thus, user inconvenience may be eliminated.

While exemplary embodiments have been shown and described above, it will be apparent to those skilled in the art that modifications and variations could be made without departing from the scope of the present disclosure as defined by the appended claims.

What is claimed is:

1. A system for providing information on the current state of business of a local goods or services provider, the system comprising:
a power consumption information collection unit collecting power consumption information of the local goods or services provider;
a power consumption information analysis unit analyzing the power consumption information collected by the power consumption information collection unit and extracting a feature of the amount of power consumption of the local goods or services provider; and
a business open-or-closed determination unit determining whether the local goods or services provider is open for business at a predetermined point in time, on the basis of the feature of the amount of power consumption of the local goods or services provider analyzed by the power consumption information analysis unit, and providing information on whether the local goods or services provider is open for business.

2. The system of claim 1, wherein when an absolute amount of power consumption measurement value of the local goods or services provider per unit time exceeds a preset first threshold value, the business open-or-closed determination unit determines that the local goods or services provider is open for business.

3. The system of claim 1, wherein a degree of increment in the amount of power consumption of the local goods or services provider per unit time exceeds a preset second threshold value, the business open-or-closed determination unit determines that the local goods or services provider is open for business, and when a degree of decrement in the amount of power consumption of the local goods or services provider exceeds a preset third threshold value, the business open-or-closed determination unit determines that the local goods or services provider is closed.

4. The system of claim 1, wherein the business open-or-closed determination unit determines whether the local goods or services provider is open for business by checking whether essential operating equipment provided in the local goods or services provider is in use.

5. The system of claim 4, wherein the business open-or-closed determination unit determines whether the essential operating equipment is in use on the basis of a signal output by a sensor installed in the essential operating equipment.

6. The system of claim 4, wherein the business open-or-closed determination unit determines whether the essential operating equipment is operating, on the basis of an electrical feature when the essential operating equipment operates.

7. The system of claim 1, further comprising an electricity meter installed in the local goods or services provider, periodically measuring an amount of power consumption of the local goods or services provider, and providing measured power consumption information and a unique identifier of the local goods or services provider to the power consumption information collection unit.

8. The system of claim 1, further comprising:
an opening/closing time prediction unit predicting a business opening/closing time of the local goods or services provider; and
an integrated result obtaining unit integrating results output from the business open-or-closed determination unit and the opening/closing time prediction unit.

9. The system of claim 8, wherein the opening/closing time prediction unit calculates a due closing time or a due opening time on the basis of results obtained by reflecting one or more of day information, holiday information, and event information and analyzing power consumption information accumulated for a preset period or longer.

10. The system of claim 9, wherein the opening/closing time prediction unit calculates a due closing time or due opening time, additionally reflecting weather information or disease information.

11. The system of claim 8, wherein the opening/closing time prediction unit additionally predicts a starting time and an ending time of a lunch break.

12. The system of claim 1, further comprising:
an information mapping unit mapping the information on whether the local goods or services provider is open for business received from the business open-or-closed determination unit with the information on the local goods or services provider; and
an information providing unit providing information mapped by the information mapping unit to a user.

13. The system of claim 12, wherein the information providing unit provides the information on whether the local goods or services provider is open for business using the information on the local goods or services provider and a combination of one or more of a phrase, a diagram, and a color indicating whether the local goods or services provider is open for business.

14. The system of claim 12, wherein the information providing unit provides the information on whether the local goods or services provider is open for business to a location of the local goods or services provider, using one or more of a figure and a color, on a map.

15. The system of claim 8, further comprising:
an information mapping unit mapping information transmitted from the integrated result obtaining unit with the information on the local goods or services provider; and
an information providing unit providing information mapped by the information mapping unit to a user.

16. The system of claim 15, wherein the information providing unit provides whether the local goods or services provider is open for business using the information on the local goods or services provider and a combination of one or more of a phase, a diagram, and a color indicating whether the local goods or services provider is open for business and a due opening/closing time.

17. The system of claim 15, wherein the information providing unit provides whether the local goods or services provider is open for business and a due opening/closing time to a location of the local goods or services provider using one or more of a figure and a color on a map.

18. A method for providing information on the current state of business of a local goods or services provider, the method comprising:
measuring an amount of power consumption of a local goods or services provider;
analyzing measured power consumption information;
determining whether the local goods or services provider is open for business on the basis of an analysis result; and
mapping information on whether the local goods or services provider is open for business with information on the local goods or services provider and providing mapped information.

19. The method of claim 18, further comprising:
predicting a business opening/closing time of the local goods or services provider; and
integrating the information on whether the local goods or services provider is open for business and the information on the business opening/closing time.
